(19) United States
(12) Patent Application Publication
(10) Pub. No.: US 2010/0046271 A1
(43) Pub. Date: Feb. 25, 2010

(54) SEMICONDUCTOR MEMORY DEVICE, METHOD OF MANUFACTURING SEMICONDUCTOR MEMORY DEVICE AND METHOD OF WRITING DATA INTO SEMICONDUCTOR MEMORY DEVICE

(75) Inventor: Yuki YAMADA, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/510,624

(22) Filed: Jul. 28, 2009

(30) Foreign Application Priority Data
Aug. 25, 2008 (JP) 2008-215849

(51) Int. Cl. G11C 11/22; G11C 7/00; G11C 11/24; H01S 4/00

(52) U.S. Cl. 365/145; 365/189.16; 365/149; 29/592.1

(57) ABSTRACT

A method of manufacturing a semiconductor memory device including a ferroelectric random access memory serving as a ROM, the method comprising: writing data into the ferroelectric random access memory, the data having a polarity opposite to that of ROM data; performing bake processing for a predetermined time period; and writing the ROM data into the ferroelectric random access memory.

### CROSS-REFERENCE TO RELATED APPLICATION

This application is based on and claims the benefit of priority from the prior Japanese Patent Application No. 2008-215849, filed on Aug. 25, 2008, the entire contents of which are incorporated herein by reference.

### BACKGROUND OF THE INVENTION

1. Field of the Invention

The present invention relates to a semiconductor memory device, a method of manufacturing a semiconductor memory device and a method of writing data into a semiconductor memory device.

2. Description of the Related Art

A ferroelectric random access memory (hereinafter referred to as FeRAM) is known as one of nonvolatile semiconductor memory devices. A FeRAM includes a ferroelectric capacitor in its memory cell and is capable of holding data without power supply, with the use of remnant polarization of its ferroelectric capacitor.

In terms of a FeRAM, it is known that a hysteresis of remnant polarization of the ferroelectric capacitor shifts depending on a condition or environment under which the FeRAM is used. Such characteristic of a FeRAM causes phenomena such as static imprint and dynamic imprint. The static imprint is that: when the FeRAM with certain data written therein is left under high temperature, it becomes difficult to write, into the FeRAM, data of a polarity opposite to that of the written data. Meanwhile, the dynamic imprint is that: when the same data is repeatedly read out, a margin for reading out the data is reduced, which gradually makes it difficult and eventually impossible to read out the data from the FeRAM.

Generally, these imprint phenomena have been considered to reduce reliability of a FeRAM. However, a semiconductor memory device is proposed in which the static imprint phenomenon is rather positively used to cause a FeRAM to serve as a ROM (see page 5 and FIG. 7 of Japanese Patent Application Publication No. Hei 10-150157, for example).

The proposed semiconductor memory device is formed as a ROM in a way that a FeRAM has data written thereto firstly, and then receives application of heat and a pulse voltage of the same polarity as the written data to cause a ferroelectric capacitor to enter a static imprint state.

However, the ROM formed in this manner has a shift of the hysteresis toward the polarity of the written data, and thus has a small margin for reading out the data. Accordingly, the ROM has a problem of reduction in the number of data read times until data cannot be read out any more due to the occurrence of the dynamic imprint phenomenon and the static imprint phenomenon.

### SUMMARY OF THE INVENTION

According to an aspect of the present invention, there is provided a method of manufacturing a semiconductor memory device including a ferroelectric random access memory serving as a ROM, the method comprising: writing data into the ferroelectric random access memory, the data having a polarity opposite to that of ROM data; performing bake processing for a predetermined time period; and writing the ROM data into the ferroelectric random access memory.

According to another aspect of the present invention, there is provided a method of manufacturing a semiconductor memory device including a ferroelectric random access memory partitioned into a ROM region and a RAM region, the method comprising: forming a circuit controlling the ROM region and the RAM region separately; writing data into the ROM region, the data having a polarity opposite to that of ROM data; performing bake processing for a predetermined time period; and writing the ROM data into the ROM region.

According to another aspect of the present invention, there is provided a method of writing data into a semiconductor memory device, the method comprising: a first step of writing data into a ferroelectric random access memory cell, the data having a polarity opposite to that of data to be actually written; a second step of performing bake processing on the ferroelectric random access memory cell; and a third step of writing into the ferroelectric random access memory cell the data to be actually written.

### BRIEF DESCRIPTION OF THE DRAWINGS

FIG. 1 is a process flowchart showing an example of a method of manufacturing a semiconductor memory device according to Embodiment 1 of the present invention.

FIGS. 2A and 2B are explanatory diagrams showing a hysteresis shift by bake processing.

FIGS. 3A and 3B are explanatory diagrams showing hysteresis shifts by a dynamic imprint phenomenon.

FIG. 4 is a block diagram showing a configuration example of a semiconductor memory device according to Embodiment 2 of the present invention.

FIG. 5 is a process flowchart showing an example of a method of manufacturing the semiconductor memory device according to Embodiment 2 of the present invention.

FIG. 6 is a block diagram showing another configuration example of the semiconductor memory device according to Embodiment 2 of the present invention.

### DESCRIPTION OF THE PREFERRED EMBODIMENT

Embodiments of the present invention will be described hereinbelow referring to the drawings.

### Embodiment 1

In this embodiment, a description is given of a method of writing ROM data into a FeRAM in a semiconductor memory device, when the FeRAM is used as a ROM.

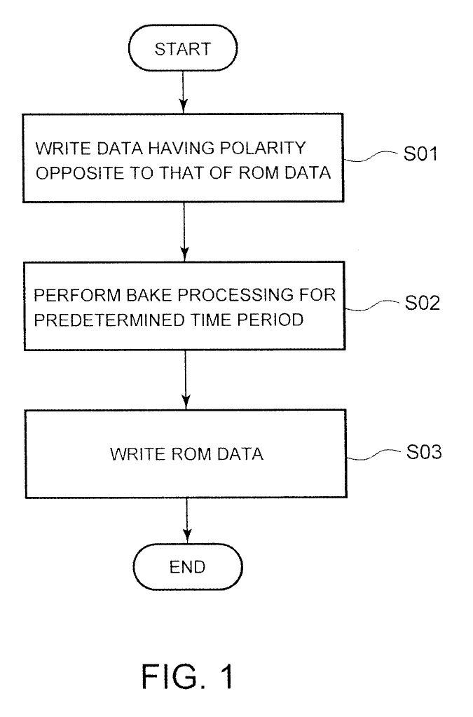

FIG. 1 is a flowchart showing an example of a process flow of writing ROM data in the present embodiment.

With the start of the writing process, firstly, data is written into a FeRAM. The data written here has an opposite polarity in which “1”s and “0”s in ROM data to be actually written are reversed (Step S01).

Thereafter, the semiconductor memory device is subjected to bake processing for a predetermined time period to cause a static imprint phenomenon to appear in the FeRAM (Step S02).

Then, the actual ROM data is written into the FeRAM (Step S03), and this process flow is finished.

As described above, in the present embodiment, the data having a polarity opposite to that of the actual ROM data is once written into the FeRAM when the FeRAM is used as a ROM. Thereafter, the FeRAM is subjected to bake processing to cause the static imprint phenomenon to forcefully appear in the FeRAM. This shifts the hysteresis of the ferroelectric capacitor. Here, the hysteresis of the actual ROM data shifts toward a direction in which a data read-out margin is increased.

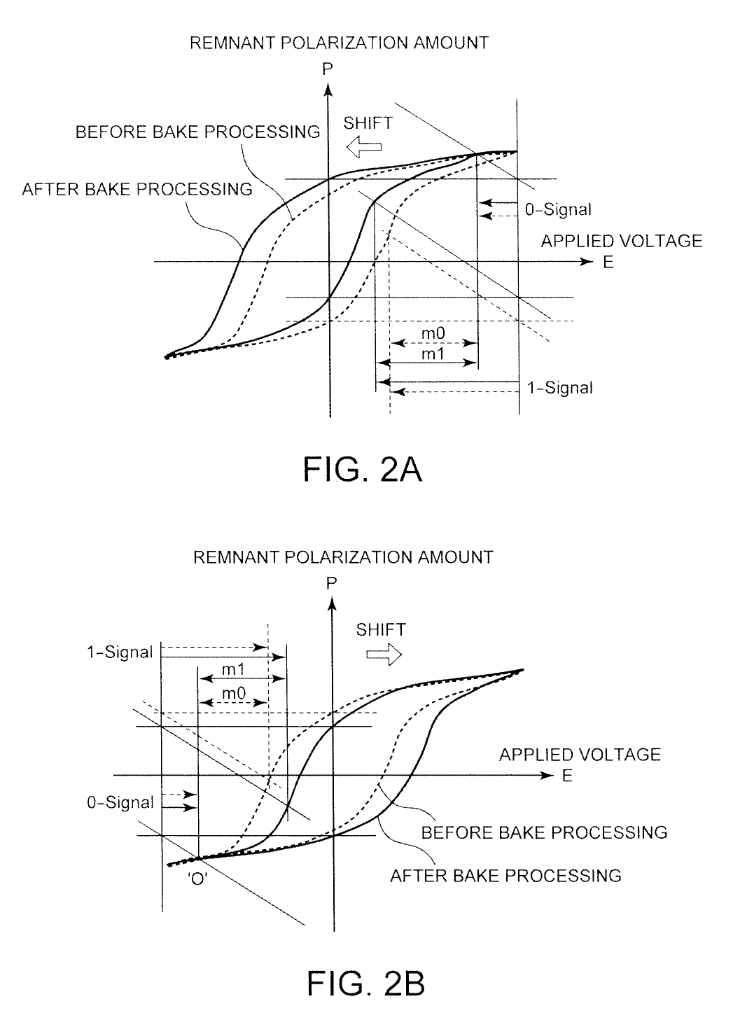

FIGS. 2A and 2B show hystereses of the ferroelectric capacitor, which are shifted by the bake processing.

FIG. 2A shows a hysteresis of the ferroelectric capacitor, obtained when bake processing is performed after “0” is written as data having an opposite polarity.

Here, with the bake processing, the hysteresis shifts to the left in FIG. 2A, i.e., from a position indicated by a dashed line in FIG. 2A to a position indicated by a solid line in FIG. 2A.

As a result, when “1” is written, as ROM data, into the ferroelectric capacitor having a hysteresis located at the position indicated by the solid line, a data read-out margin (difference between “1” level and “0” level) m1 at the time of reading out the data is more than a data read-out margin m0 in the hysteresis obtained before the bake processing.

FIG. 2B shows a hysteresis of the ferroelectric capacitor, obtained when bake processing is performed after “1” is written as data having an opposite polarity.

Here, with the bake processing, the hysteresis shifts to the right in FIG. 2B, i.e., from a position indicated by a dashed line in FIG. 2B to a position indicated by a solid line in FIG. 2B.

As a result, when “0” is written, as ROM data, into the ferroelectric capacitor having a hysteresis located at the position indicated by the solid line, a data read-out margin m1 at the time of reading out the data is, as in the above case, more than a data read-out margin m0 in the hysteresis obtained before the bake processing.

Next, a description is given of a dynamic imprint phenomenon appeared in the FeRAM having ROM data written therein.

From the FeRAM having ROM data written therein, data of the same values is always read out. For this reason, the FeRAM normally undergoes a dynamic imprint phenomenon, as well as the static imprint phenomenon caused by leaving the FeRAM under high temperature. The dynamic imprint phenomenon causes the hysteresis of the ferroelectric capacitor to shift every time data is read out. Here, the dynamic imprint phenomenon causes the hysteresis to shift to an opposite direction from the direction in which the hysteresis shifts due to the bake processing performed after writing the opposite-polarity data.

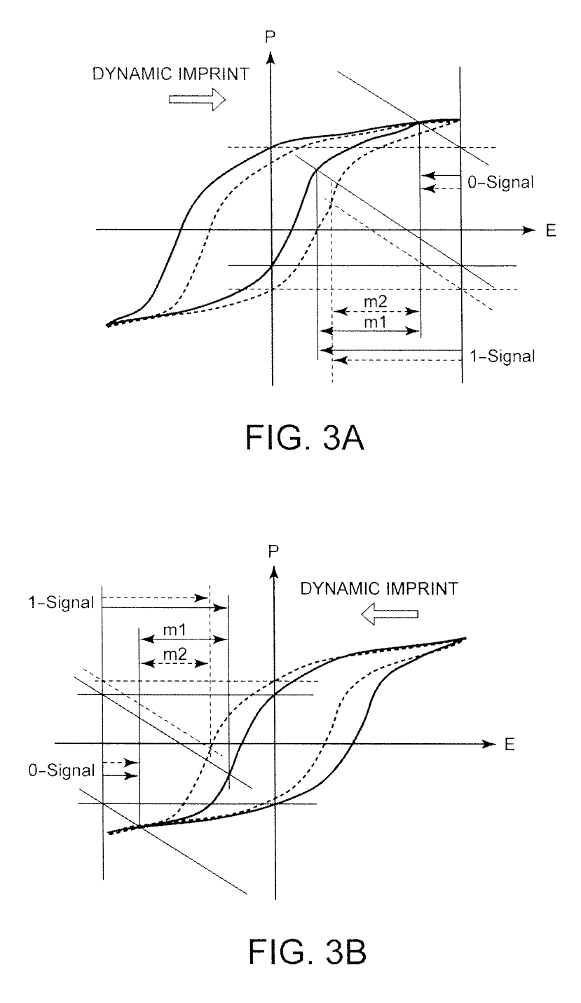

FIGS. 3A and 3B show hystereses of the ferroelectric capacitor, which are shifted due to the dynamic imprint phenomenon.

FIG. 3A shows a hysteresis (indicated in a dashed line) shifted, due to the dynamic imprint phenomenon, from the hysteresis (indicated in a solid line) obtained after the bake processing in FIG. 2A.

In this case, the hysteresis shifts to the right in FIG. 3A due to the dynamic imprint phenomenon. Accordingly, a data read-out margin m2 in the hysteresis obtained after the right shift is less than the data read-out margin m1 in the hysteresis obtained before the right shift.

FIG. 3B shows a hysteresis (indicated in a dashed line) shifted, due to the dynamic imprint phenomenon, from the hysteresis (indicated in a solid line) obtained after the bake processing in FIG. 2B.

In this case, the hysteresis shifts to the left in FIG. 3B due to the dynamic imprint phenomenon. Accordingly, a data read-out margin m2 in the hysteresis obtained after the left shift is less than the data read-out margin m1 in the hysteresis obtained before the left shift.

As described above, the appearance of the dynamic imprint phenomenon reduces the data read-out margin of the FeRAM having ROM data written therein.

In the FeRAM having ROM data written according to a method of the present embodiment, however, the data read-out margin at the start of use is increased by the bake processing. Accordingly, even if the read-out margin starts reducing due to the dynamic imprint phenomenon, the FeRAM still has a sufficient data read-out margin and is readable a considerable number of times before the occurrence of a read-out error.

In other words, compared to the conventional device, the present embodiment makes it possible to enhance a data read-out margin in a FeRAM serving as a ROM to cope with the dynamic/static imprint phenomena.

### Embodiment 2

In this embodiment, a description is given of an example of a semiconductor memory device provided with a FeRAM partitioned into a ROM region and a RAM region.

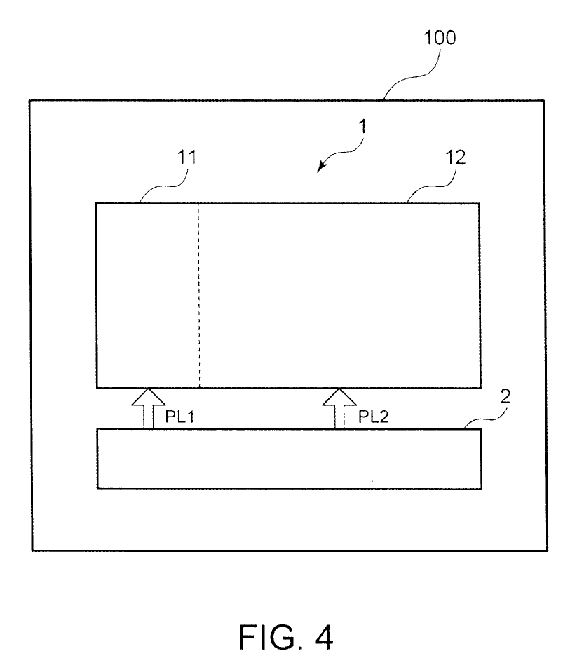

FIG. 4 is a block diagram showing a configuration example of a semiconductor memory device according to Embodiment 2 of the present invention.

A semiconductor memory device 100 of the present embodiment includes a FeRAM 1 and an operation control circuit 2. The FeRAM 1 is partitioned into a ROM region 11 and a RAM region 12.

In the present embodiment, the manufacturing method described in Embodiment 1 is used to write ROM data into the ROM region 11. If any data has already been written into the RAM region 12 before writing ROM data into the ROM region 11, a static imprint phenomenon appears also in the RAM region 12 after the bake processing. This may reduce the data read-out margin in the RAM region 12 at the actual use.

To avoid this, the operation control circuit 2 controls the operation of the FeRAM 1 to activate the ROM region 11 and the RAM region 12 separately.

To write the ROM data, the operation control circuit 2 activates only the ROM region 11, and does not activate the RAM region 12. Thus no data is written into the RAM region 12. This prevents the static imprint phenomenon from appearing in the RAM region 12 even after the bake processing.

As a specific method of such activation, FIG. 4 shows an example in which the operation control circuit 2 controls a potential of a plate line PL1 of the ROM region 11 and a potential of a plate line PL2 of the RAM region 12 individually. To write ROM data, the operation control circuit 2 provides a predetermined plate-line potential only to the plate line PL1 of the ROM region 11.

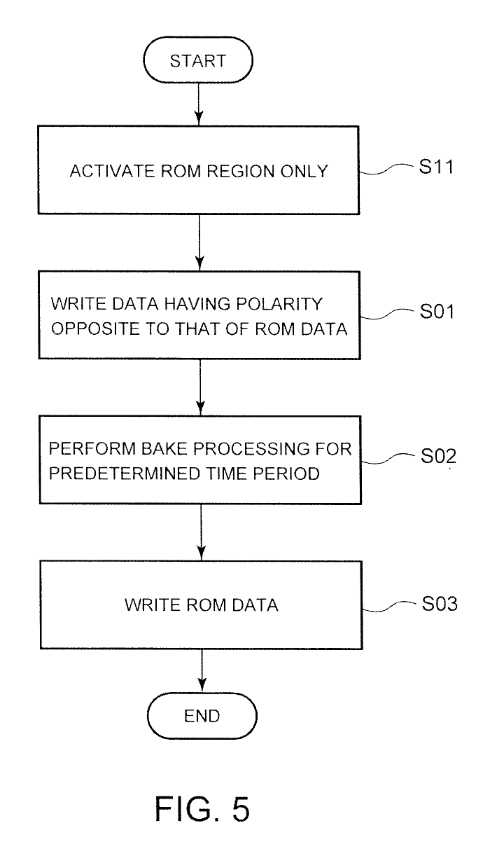

FIG. 5 is a flowchart showing an example of a process flow of writing ROM data according to the present embodiment.

The process flow of writing the ROM data according to the present embodiment is made by adding a step (Step S11) at the beginning of the process flow shown in FIG. 1. In the Step S11, only the ROM region 11 is activated by using the operation control circuit 2.

The following steps (Steps S01 to S03) are the same as the steps denoted with the same reference numerals in the flow of FIG. 1. Accordingly, any redundant explanation is avoided herein.

FIG. 4 shows an example of controlling the plate lines PL1 and PL2 as a method to activate the ROM region 11 and the RAM region 12 separately. However, it should be noted that the method for controlling activation is not limited to this.

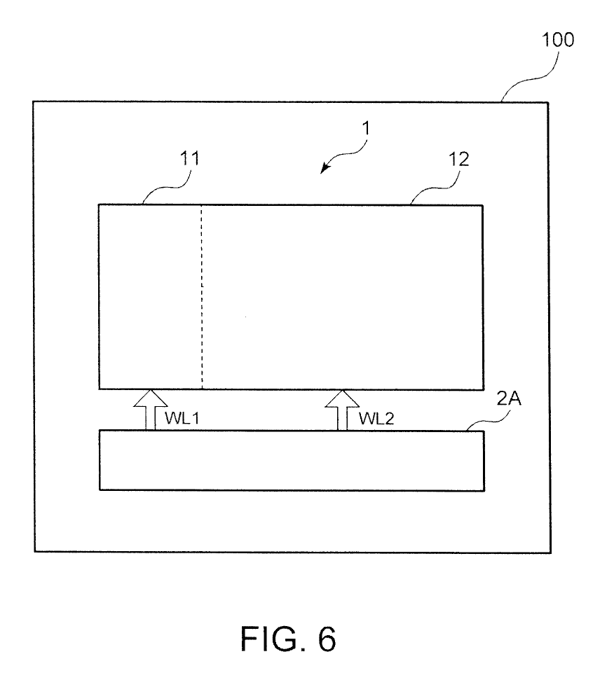

As an alternative example, as shown in FIG. 6, an operation control circuit 2A may control an access to a word line WL1 of the ROM region 11 and an access to a word line WL2 of the RAM region 12 individually. In this alternative case, the operation control circuit 2A allows an access only to the word line WL1 of the ROM region 11 to write ROM data.

According to the present embodiment, even in a FeRAM partitioned into a ROM region and a RAM region, a data read-out margin in the ROM region can be enhanced, without reduction in a data read-out margin in the RAM region, to cope with the dynamic imprint phenomenon.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A method of manufacturing a semiconductor memory device including a ferroelectric random access memory serving as a ROM, the method comprising:
writing data into the ferroelectric random access memory, the data having a polarity opposite to that of ROM data;
performing bake processing for a predetermined time period; and
writing the ROM data into the ferroelectric random access memory.

2. A method of manufacturing a semiconductor memory device including a ferroelectric random access memory partitioned into a ROM region and a RAM region, the method comprising:
forming a circuit controlling the ROM region and the RAM region separately;
writing data into the ROM region, the data having a polarity opposite to that of ROM data;
performing bake processing for a predetermined time period; and
writing the ROM data into the ROM region.

3. A semiconductor memory device comprising:
a ferroelectric random access memory partitioned into a ROM region and a RAM region; and
an operation control circuit which operates the ROM region and the RAM region separately, wherein
ROM data is written into the ROM region in the manufacturing method of claim 2.

4. The semiconductor memory device according to claim 3, wherein
The operation control circuit individually controls a potential of a plate line of the ROM region and a potential of a plate line of the RAM region to operate the ROM region and the RAM region separately.

5. The semiconductor memory device according to claim 3, wherein
The operation control circuit controls an access to a word line to operate the ROM region and the RAM region separately.

6. A method of writing data into a semiconductor memory device, the method comprising:
a first step of writing data into a ferroelectric random access memory cell, the data having a polarity opposite to that of data to be actually written;
a second step of performing bake processing on the ferroelectric random access memory cell; and
a third step of writing into the ferroelectric random access memory cell the data to be actually written.

7. The method of writing data into a semiconductor memory device according to claim 6, wherein
the semiconductor memory device includes:
a ROM region including the ferroelectric random access memory cell;
a RAM region including the ferroelectric random access memory cell; and
an operation control circuit which selectively activates the ROM region,
the first step is a step of writing data into the ROM region, the data having a polarity opposite to that of data to be actually written, and
the second step is a step of performing bake processing after the operation control circuit activates the ROM region and deactivates the RAM region.

8. The method of writing data into a semiconductor memory device according to claim 7, wherein
the ferroelectric random access memory cell in the ROM region and the ferroelectric random access memory cell in the RAM region are coupled to different plate lines, respectively, and
in the second step, the operation control circuit provides a plate-line potential only to the plate line coupled to the ferroelectric random access memory cell of the ROM region.

9. The method of writing data into a semiconductor memory device according to claim 7, wherein
the ferroelectric random access memory cell in the ROM region and the ferroelectric random access memory cell in the RAM region are coupled to different word lines, respectively, and
in the second step, the operation control circuit allows an access only to the word line coupled to the ferroelectric random access memory cell of the ROM region.

10. The method of manufacturing a semiconductor memory device according to claim 1, wherein
the ferroelectric random access memory includes a ferroelectric capacitor.

11. The method of manufacturing a semiconductor memory device according to claim 2, wherein
the ferroelectric random access memory includes a ferroelectric capacitor.

12. The semiconductor memory device according to claim 3, wherein
the ferroelectric random access memory includes a ferroelectric capacitor.

13. The method of writing data into a semiconductor memory device according to claim 6, wherein
the ferroelectric random access memory cell includes a ferroelectric capacitor.
